(19) United States
(12) Patent Application Publication
(10) Pub. No.: US 2007/0268670 A1
(43) Pub. Date: Nov. 22, 2007

(54) Electronic device

(75) Inventors: Hung-Chun Chu, Taipei (TW); Chun-Chieh Wu, Taipei (TW)

Correspondence Address: BIRCH STEWART KOLASCH & BIRCH, PO BOX 747, FALLS CHURCH, VA, 22040-0747, US

(73) Assignee: ASUSTeK COMPUTER INC.

(21) Appl. No.: 11/798,437

(22) Filed: May 14, 2007

(30) Foreign Application Priority Data
May 16, 2006 (TW) 95117363

(51) Int. Cl. H05K 7/20

(52) U.S. Cl. 361/702; 361/711; 165/80.3; 165/104.33

(57) ABSTRACT

An electronic device with a heat dissipation device is described. A printed circuit board has a first electronic component and a second electronic component thereon. The first dissipation device is attached to the first electronic component. The second dissipation device is attached to the second electronic component. At least one heat pipe includes a first straight section, a second straight section and a bent section between the former two. The heat pipe penetrates the first dissipation device and the second dissipation device, wherein the second dissipation device has at least one side engraved slot for securing the heat pipe inside.

### RELATED APPLICATIONS

This application claims priority to Taiwan Application Serial Number 95117363, filed May 16, 2006, which is herein incorporated by reference.

### BACKGROUND

1. Field of Invention

The present invention relates to an electronic device. More particularly, the present invention relates to an electronic device with a heat dissipation device.

2. Description of Related Art

As operation frequencies of various electrical processors increase, the reliable operation of the processors is increasingly dependent on heat dissipation devices. The dissipation devices are able to maintain lower temperatures for working electrical processors and therefore improve processor efficiency and prevent processor malfunctions.

Heat dissipation devices are usually attached to and remove heat from high power electrical devices (such as CPUs). Heat generated by other components is removed by air convection driven by a system fan. However, higher frequency processors, e.g. CPUs, Northbridge chipsets and Southbridge Chipsets, are being installed on computer system motherboards and are consequently producing more heat than before. Conventional heat dissipation methods cannot satisfy such demanding requirements.

### SUMMARY

It is therefore an objective of the present invention to provide a series-connected dissipation fin module to increase overall heat dissipation efficiency.

In accordance with the foregoing and other objectives of the present invention, an electronic device with a heat dissipation device is provided. A printed circuit board has a first electronic component and a second electronic component thereon. The first dissipation device is attached to the first electronic component. The second dissipation device is attached to the second electronic component. At least one heat pipe includes a first straight section, a second straight section and a bent section between the first straight section and the second straight section. The heat pipe penetrates the first dissipation device and the second dissipation device, wherein the second dissipation device has a engraved slot on at least one side to secure the heat pipe inside.

According to preferred embodiments, the first dissipation device includes a first dissipation base and a first dissipation fin module, and the heat pipe penetrates the first dissipation fin module. The first dissipation base is attached to the first electronic component, and the first dissipation fin module is secured to the first dissipation base. The second dissipation device includes a second dissipation base and a second dissipation fin module, and the heat pipe penetrates the second dissipation fin module. The second dissipation base is attached to the second electronic component, and the second dissipation fin module is secured to the second dissipation base. The engraved slot is disposed on one side of the second dissipation fin module to secure the heat pipe inside.

Thus, multiple dissipation fin modules can be connected by pre-bent heat pipes while engraved slots are designed on one side of the dissipation fin modules. Besides, multiple dissipation fin modules connected in series increase the overall heat dissipation efficiency so as to meet the requirements of high power devices.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a heat dissipation device in an electronic device according to one preferred embodiment of this invention;

FIG. 2 illustrates a dissipation fin module in a heat dissipation device according to one preferred embodiment of this invention; and

FIG. 3 illustrates a heat pipe in a heat dissipation device according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

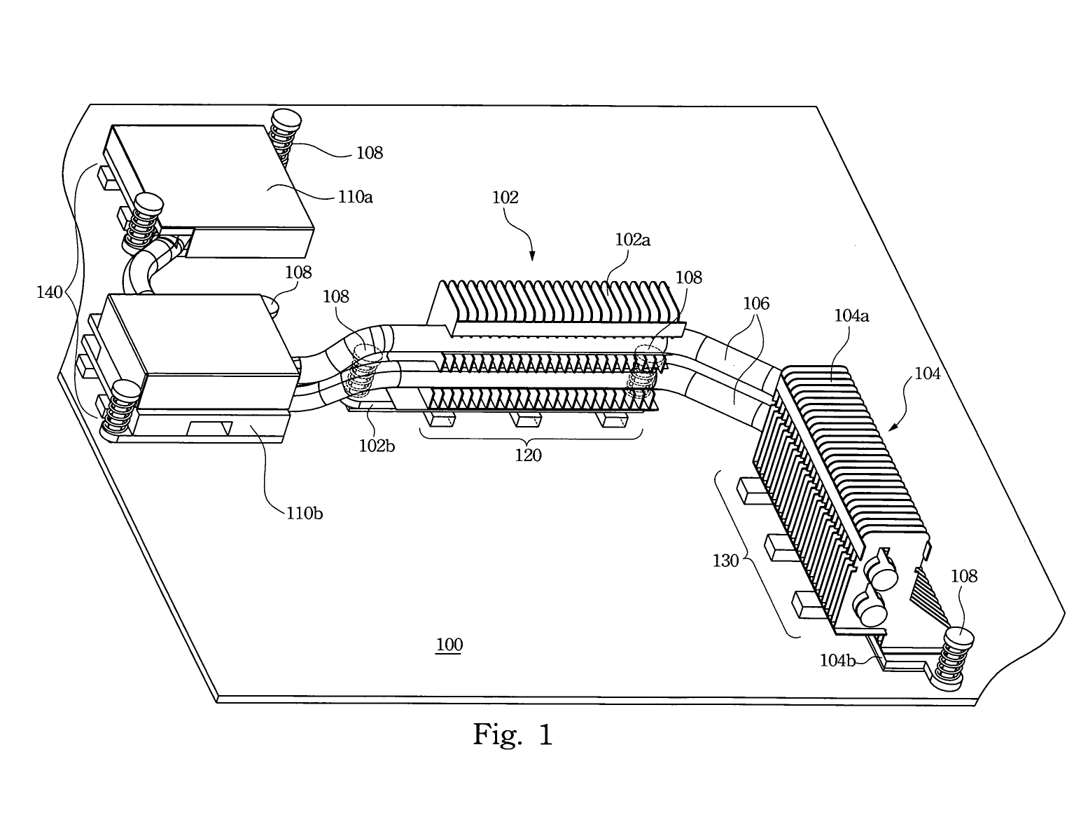

FIG. 1 illustrates a heat dissipation device in an electronic device according to one preferred embodiment of this invention. A printed circuit board 100 is installed in an electronic device, and a heat dissipation device is disposed thereon. The printed circuit board 100 can be a motherboard on which a first electronic component 130 and a second electronic component 120 (such as two integrated semiconductor circuits) are installed thereon. A first heat dissipation device 104 is attached to the first electronic component 130 for removing heat thereof. A second heat dissipation device 102 is attached to the second electronic component 120 for removing heat thereof. The first heat dissipation device 104 includes a first dissipation fin module 104a and a first dissipation base 104b. The first dissipation fin module 104a is secured to the first dissipation base 104b. The first dissipation base 104b is attached to the first electronic component 130 by means of fastening devices 108 (one fastening device is not shown in FIG. 1) disposed around the first dissipation base 104b. The second heat dissipation device 102 includes a second dissipation fin module 102a and a second dissipation base 102b. The second dissipation fin module 102a is secured to the second dissipation base 102b. The second dissipation base 102b is attached to the second electronic component 120 by means of fastening devices 108 disposed around the first dissipation base 102b.

In order to increase efficiency of the whole heat dissipation device, one or multiple heat pipes 106 penetrate the first dissipation device 104 and the second dissipation device 102. Therefore, heat generated by the first electronic component 130 and the second electronic component 120 is removed both by the first dissipation device 104 and the second dissipation device 102. The heat pipe 106 also reaches to a third dissipation base 110a and a fourth dissipation base 110b to remove more heat generated by other electronic components.

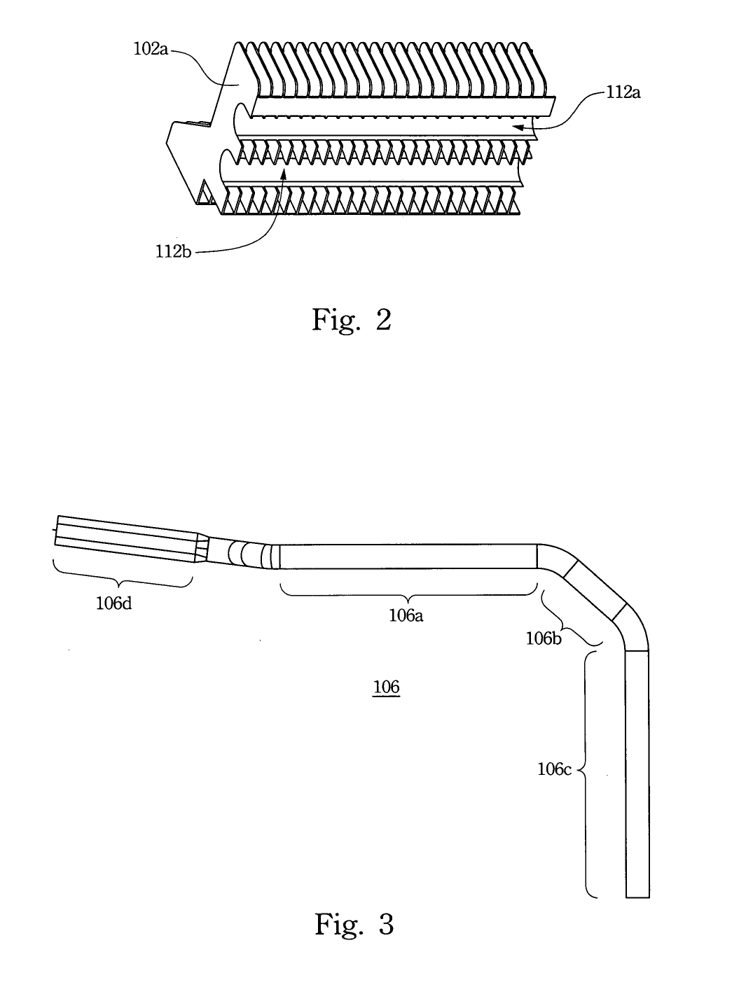

FIG. 2 illustrates a dissipation fin module in a heat dissipation device according to one preferred embodiment of this invention. FIG. 3 illustrates a heat pipe in a heat dissipation device according to one preferred embodiment of this invention.

Reference will now be made to FIG. 1, FIG. 2 and FIG. 3. In order to overcome difficulties in assembling dissipation devices, the second dissipation fin module 102a has two engraved slots 112a and 112b on one side thereof. When the first dissipation device 104, the second dissipation device 102 and the heat pipe 106 are assembled, it is not possible to insert the heat pipe 106 through holes (not engraved slots 112a and 112b) of the first dissipation fin module 104a and second dissipation fin module 102a because the heat pipe 106 has a bent section 106b. Therefore, two engraved slots 112a and 112b are designed on one side of the second dissipation fin module 102a such that a second straight section 106a of the heat pipe 106 can be secured in the two engraved slots 112a or 112b. In addition, a third straight section 106d of the heat pipe 106 is connected with the third dissipation base 110a and the fourth dissipation base 110b, which are attached to a third electronic component 140.

According to preferred embodiments of the present invention, multiple dissipation fin modules can be connected by a pre-bent heat pipe and one side of the dissipation fin modules has engraved slots. Besides, connecting multiple dissipation fin modules in series increases overall heat dissipation efficiency so as to meet requirements of high power devices.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An electronic device, comprising:
a printed circuit board, having a first electronic component and a second electronic component;
a first dissipation device, attached to the first electronic component;
a second dissipation device, attached to the second electronic component; and
at least one heat pipe, having a bent section, a first straight section and a second straight section, the bent section being between the first straight section and the second straight section, the heat pipe penetrating the first dissipation device and the second dissipation device;
wherein the second dissipation device has an engraved slot disposed on one side thereof, and the heat pipe is secured in the engraved slot.

2. The electronic device of claim 1, wherein the first dissipation device includes a first dissipation base and a first dissipation fin module, and the heat pipe penetrates the first dissipation fin module.

3. The electronic device of claim 2, wherein the first dissipation base is attached to the first electronic component, and the first dissipation fin module is secured to the first dissipation base.

4. The electronic device of claim 1, wherein the second dissipation device includes a second dissipation base and a second dissipation fin module, and the heat pipe penetrates the second dissipation fin module.

5. The electronic device of claim 4, wherein the second dissipation base is attached to the second electronic component, and the second dissipation fin module is secured to the second dissipation base.

6. The electronic device of claim 4, wherein the engraved slot is disposed on one side of the second dissipation fin module.

7. The electronic device of claim 1, wherein the printed circuit board is a motherboard.

8. The electronic device of claim 1, further comprising multiple fastening devices disposed around the first dissipation base and the second dissipation base to secure thereof to the printed circuit board.

9. The electronic device of claim 1, wherein the first electronic component and the second electronic component are integrated semiconductor circuits.

10. The electronic device of claim 1, further comprising at least one third dissipation base attached to a third electronic component and the third dissipation base being connected with the heat pipe.
